(19) United States
(12) Patent Application Publication
(10) Pub. No.: US 2019/0179214 A1
(43) Pub. Date: Jun. 13, 2019

(54) WATERPROOF LID OPENING-CLOSING STRUCTURE AND ELECTRONIC DEVICE INCLUDING THE SAME

(71) Applicant: JVC KENWOOD CORPORATION, Yokohama-shi (JP)

(72) Inventor: Noriyuki HARA, Yokohama-shi (JP)

(21) Appl. No.: 16/200,979

(22) Filed: Nov. 27, 2018

(30) Foreign Application Priority Data
Dec. 8, 2017 (JP) 2017-235676

(51) Int. Cl. G03B 17/08; H05K 5/03; H05K 5/02

(52) U.S. Cl. CPC G03B 17/08; H05K 5/0286; H05K 5/0226; H05K 5/03

(57) ABSTRACT

A waterproof lid-opening-closing structure includes a packing member, a holder, a lid, a slide-biasing member, a lock-release knob, and a lock-biasing member. The holder to which a packing member is attached is connected to a case by a hinge. The lid engages with the holder in an engagement portion configured to allow the lid to slide in a direction intersecting an axis of the hinge. The lock-release knob attached to the lid and biased by the lock-biasing member is movable and restricts or allows the sliding of the lid relative to the holder. The engagement portion includes first portion and the second portion of the lid divided in a direction of the axis. The slide-biasing member biasing the lid in a direction away from the axis includes a first slide biasing member and a second biasing member disposed outside and adjacent to the first portion and the second portion, respectively.

### CROSS REFERENCE TO RELATED APPLICATION

This application is based upon and claims the benefit of priority from the prior Japanese Patent Application No. 2017-235676 (filing date: Dec. 8, 2017), the entire contents of which are incorporated herein by reference.

### TECHNICAL FIELD

The present invention relates to a waterproof lid opening-closing structure and an electronic device including the same.

### RELATED ART

A waterproof opening-closing lid provided in a case of an electronic device is known and Japanese Patent Application Publication No. 2003-152351 describes a camera including the opening-closing lid.

The conventional opening-closing lid described in Japanese Patent Application Publication No. 2003-152351 is a lid configured to open and close a storage portion which is provided in a ridge portion between a side surface and a rear surface of the case and which houses a card and the like and can be locked in a closed state.

When opening the lid, a user slides a lid opening switch disposed on a bottom surface of the case to unlock the lid and then turns the lid.

### SUMMARY

The conventional opening-closing lid has a problem that, when opening the lid, the user needs to perform two independent operations of the sliding operation of the lid opening switch and the turning operation of the lid, which take time and effort.

The conventional opening-closing lid also has a problem that, since the two independent operations are performed in different portions of the case, the opening operation of the lid and the method thereof are difficult for the user to intuitively understand.

Thus, the conventional waterproof opening-closing lid is desired to be improved in operability of opening it.

An object of the present invention is to provide a waterproof lid opening-closing structure and an electronic device with excellent operability of opening a lid.

A waterproof lid opening-closing structure according to an aspect of the present invention includes a packing member tightly fitted to the opening portion and configured to close an opening portion of a case, a holder connected to the case by a hinge portion and to which the packing member is attached, the holder configured to turn about an axis of the hinge portion between a closed position where the packing member closes the opening portion and an open position where the packing member opens the opening portion, a lid engaging with the holder in an engagement portion configured to allow the lid to slide by a predetermined stroke in a direction intersecting the axis, a slide biasing member biasing the lid in a direction away from the axis, a lock release knob attached to the lid and which is movable to a first position where the sliding of the lid relative to the holder is restricted and a second position where the sliding is allowed, and a lock biasing member biasing the lock release knob toward the first position. The engagement portion includes a first engagement portion formed in one of two portions of the lid which are divided in a direction of the axis and a second engagement portion formed in another one of the two portions. The slide biasing member includes a first slide biasing member disposed outside and adjacent to the first engagement portion and a second slide biasing member disposed outside and adjacent to the second engagement portion.

The waterproof lid opening-closing structure according to an aspect of the present invention provides a waterproof lid opening-closing structure and an electronic device with excellent operability of opening a lid.

### BRIEF DESCRIPTION OF DRAWINGS

FIG. 1 is a perspective view illustrating a video camera 51 which is Example 1 of an electronic device according to an embodiment of the present invention.

FIG. 2 is a first view for explaining an operation of a lid opening-closing structure K provided in the video camera 51.

FIG. 3 is a second view for explaining the operation of a lid opening-closing structure K.

FIG. 4 is an assembly view of a lid body 11 included in the lid opening-closing structure K.

FIG. 5 is a plan illustrating a lid 13 included in the lid body 11.

FIG. 6 is a cross-sectional view at the position S06-06 in FIG. 5.

FIG. 7A is a cross-sectional view at the position S07-S07 in FIG. 1 and FIG. 7B is a plan of a lock release knob 12 included in the lid body 11.

FIG. 8 is a plan illustrating a holder 15 included in the lid body 11.

FIG. 9 is a cross-sectional view at the position S09-S09 in FIG. 8.

FIG. 10 is a plan illustrating a cam groove 15a formed in the holder 15.

FIG. 11 is a schematic view for explaining a structure of the lid opening-closing structure K.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

Description will be hereinbelow provided for embodiments of the present invention by referring to the drawings. It should be noted that the same or similar parts and components throughout the drawings will be denoted by the same or similar reference signs, and that descriptions for such parts and components will be omitted or simplified. In addition, it should be noted that the drawings are schematic and therefore different from the actual ones.

A waterproof lid opening-closing structure according to an embodiment of the present invention and an electronic device including the same are described by using a lid opening-closing structure K of Example and a video camera 51 including the same.

### Example

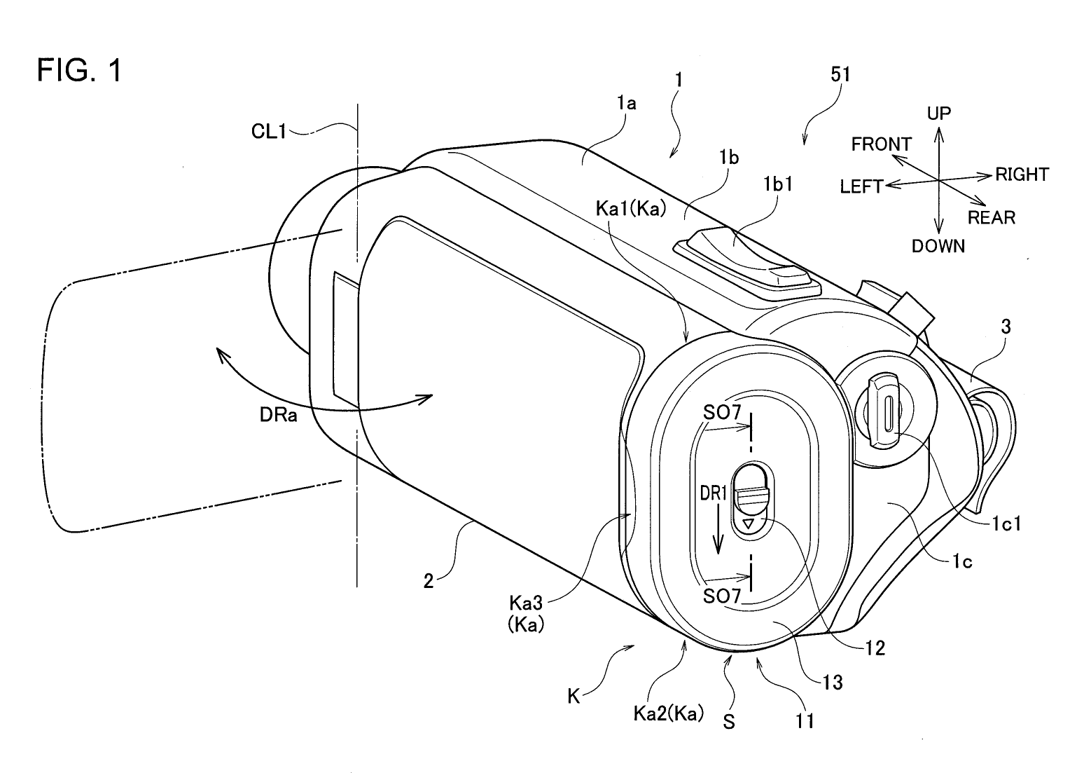

FIG. 1 is a perspective view of the lid opening-closing structure K and the video camera 51 including the same as viewed obliquely from the rear left side. Hereafter, the directions of front, rear, left, right, up, and down of the video camera 51 are defined as illustrated by the arrows in FIG. 1 for the sake of explanation. The front side is a side where a subject to be imaged is present.

The video camera 51 includes a main body portion 1 which has a case 1a, an image display portion 2 which can be opened and closed by being turned (arrow DRa) about an axis CL1 extending in the up-down direction on a left surface of the main body portion 1, and a grip belt 3 which is provided on a right surface of the main body portion 1 and which comes into contact with the back of the hand of a user gripping the main body portion 1. A zoom button 1b1 is disposed on an upper surface 1b of the main body portion 1. Moreover, a recording button 1c1 used to perform an operation of starting and stopping the recording is disposed in an upper right portion of a rear surface 1c and substantially the left half of the main body portion 1 is a storage portion S.

The video camera 51 includes an opening-closing lid body 11 (hereafter, also referred to simply as lid body 11) which closes an opening portion Sa of the storage portion S in a waterproof manner in a closed state and which opens an inside of the storage portion S in an open state. The lid body 11 includes a lock release knob 12 which can be operated by being pushed down by the finger. In this example, the lock release knob 12 is disposed substantially at the center of the lid body 11.

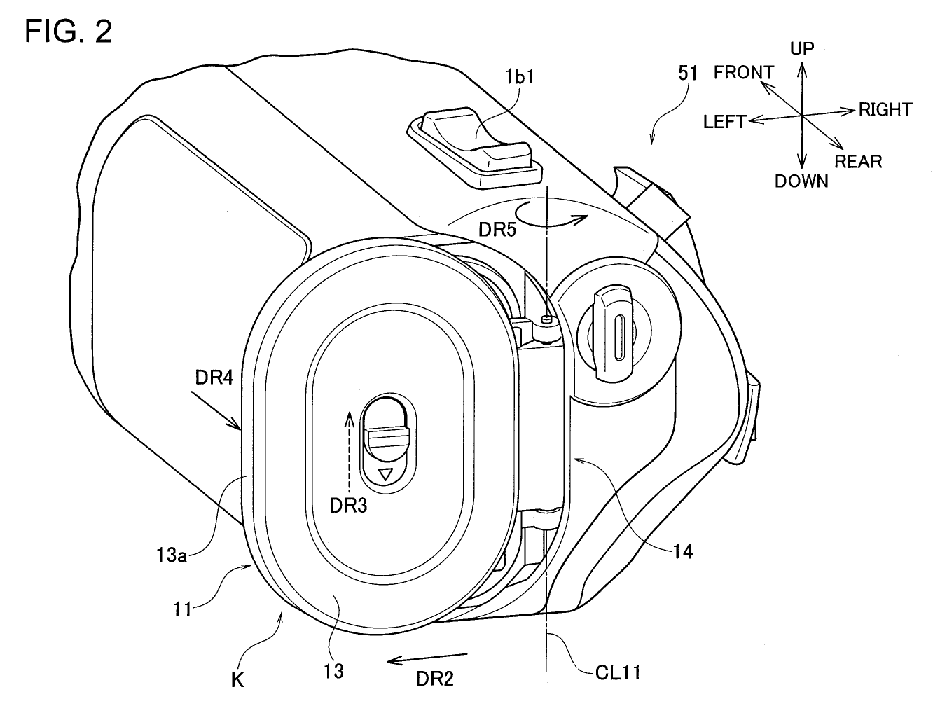

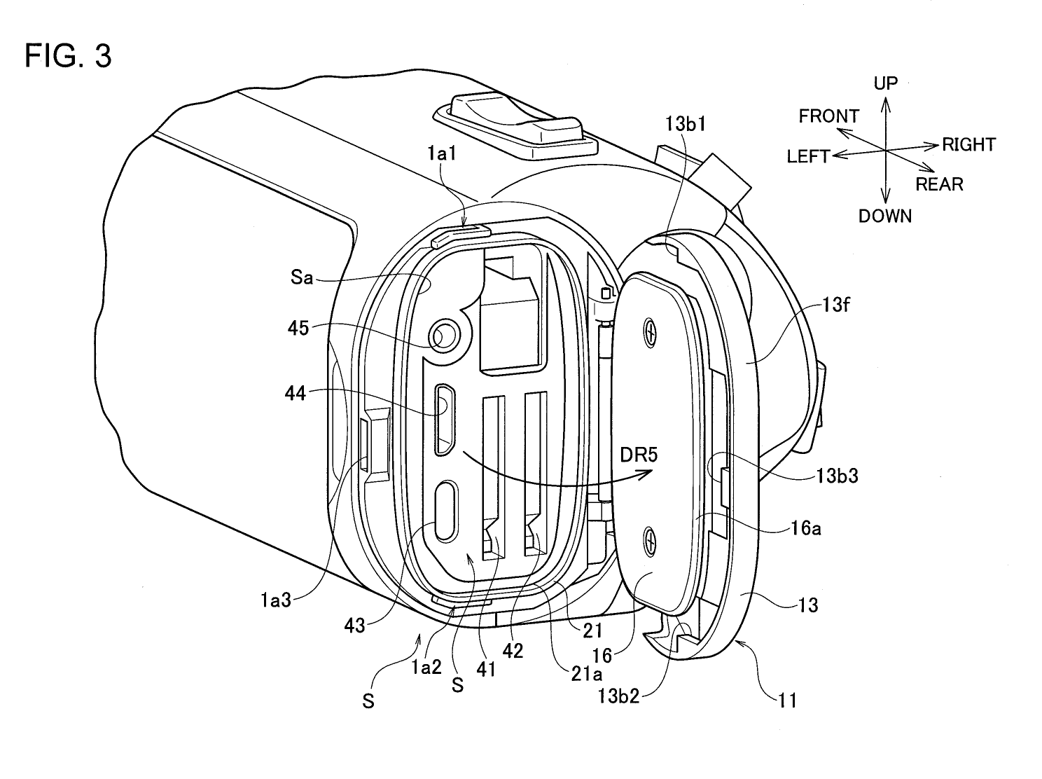

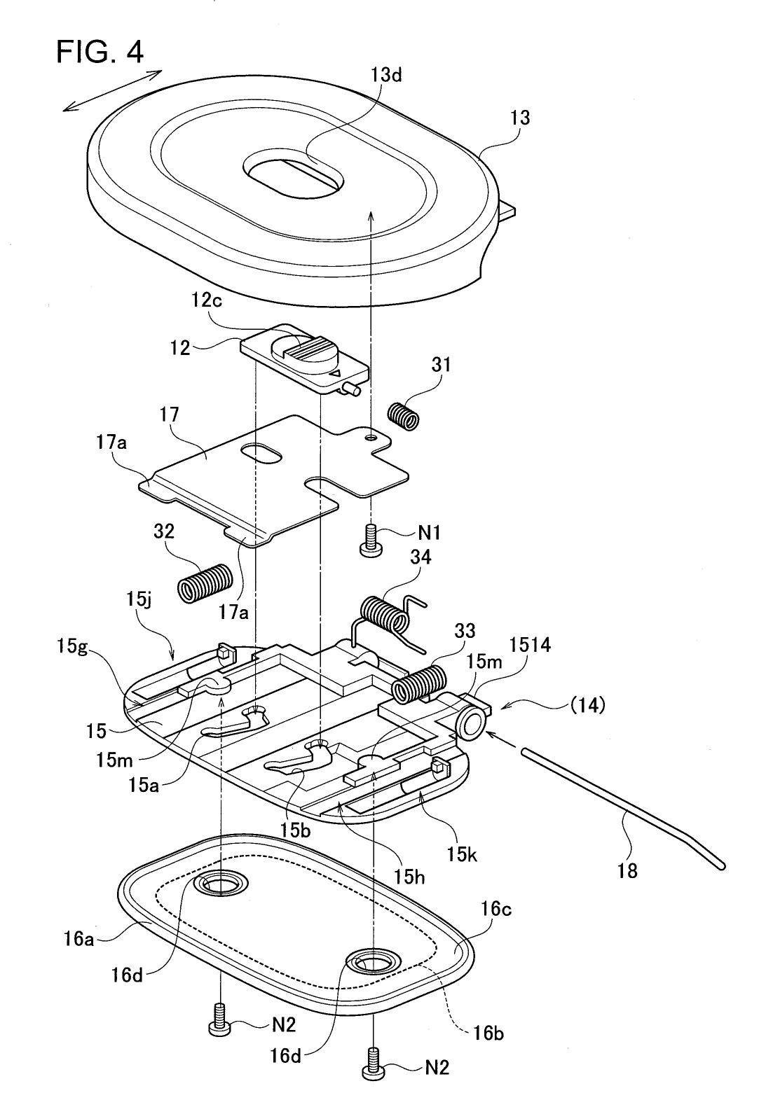

The lid body 11 can be opened by performing the operation described below. In order to facilitate the understanding of the structure, the opening operation and modes of the structure are described prior to the detailed structure with reference to FIGS. 2 to 4. FIGS. 2 and 3 are partial perspective views illustrating modes in the opening operation of the lid body 11. FIG. 4 is an assembly view of the lid body 11.

When opening the closed lid body 11, the user first pushes down (arrow DR1) the lock release knob 12 in the state illustrated in FIG. 1 with the finger. Since the lock release knob 12 is moderately biased upward by a compression resilient force of a knob coil spring 31 (see FIG. 4) which is a biasing member, the user pushes down the lock release knob 12 against this compression resilient force.

Pushing down the lock release knob 12 cancels restriction of leftward movement of a lid 13 relative to a holder 15 (see FIG. 4), the lid 13 and the holder 15 being an exterior member and an interior member of the lid body 11, respectively. The lid 13 thereby slides leftward (FIG. 2: arrow DR2) by a predetermined stroke by itself due to compression resilient forces of paired slide coil springs 32, 33 (see FIG. 4) disposed inside the lid 13 as biasing members.

As illustrated in FIG. 2, a hinge portion 14 is exposed to the outside with the leftward sliding of the lid 13, the hinge portion 14 supporting the lid body 11 such that it is turnable about an axis CL11 extending in the up-down direction. The hinge portion 14 is a turning engagement portion between the holder 15 being the interior member and the case 1a of the main body portion 1. Moreover, the leftward sliding of the lid 13 cancels engagement in an engagement portion Ka which restricts counterclockwise turning of the lid 13 as viewed from above (arrow DR5) by means of interference between members (see FIG. 1) and the lid 13 is set to a state where this turning is allowed.

The engagement portion Ka includes three portions of an upper engagement portion Ka1, a lower engagement portion Ka2, and a side engagement portion Ka3 whose positions are roughly illustrated in FIG. 1 by the reference numerals. Description is given with reference to FIG. 3. The upper engagement portion Ka1 is configured to include an upper groove portion 1a1 which is formed near and outside an upper edge of the storage portion S in the case 1a to extend in the left-right direction and an upper rib 13b1 which protrudes downward in an inner surface upper portion of the lid 13 and which engages with the upper groove portion 1a1 by sliding to advance into the upper groove portion 1a1. The lower engagement portion Ka2 is configured to include a lower groove portion 1a2 which is formed near and outside a lower edge of the storage portion S in the case 1a to extend in the left-right direction and a lower rib 13b2 which extends upward in an inner surface lower portion of the lid 13 and which engages with the lower groove portion 1a2 by advancing into the lower groove portion 1a2 in the closed state. The side engagement portion Ka3 is configured to include a pocket portion 1a3 which is provided near and outside a left edge of the storage portion S in the case 1a and which has a pocket-shaped space formed to spread in the left-right direction and the up-down direction and a side rib 13b3 which protrudes toward the hinge portion 14 in a side edge portion of the lid 13 away from the hinge portion 14 and which engages with the pocket portion 1a3 by sliding to advance into the pocket portion 1a3.

The hinge portion 14 allows the lid body 11 to slightly move relative to the case 1a in the up-down direction and the radial direction to give priority to position restriction of the lid body 11 in the closed state and position restriction by tight fitting of a packing plate 16 to the storage portion S to be described later. In other words, so-called backlash is intentionally provided.

The hinge portion 14 includes a torsion coil spring 34 (see FIG. 4) which biases the lid body 11 counterclockwise (in an opening direction) as viewed from above. Although the lid body 11 is biased counterclockwise about the axis CL11 as viewed from above by the turning biasing force of the torsion coil spring 34, the tight fitting of the packing plate 16 to the storage portion S keeps the lid body 11 in the state illustrated in FIG. 2.

In FIG. 3, substantially the entire packing plate 16 is covered with silicone rubber and at least an entire periphery of a peripheral edge portion 16a of the packing plate 16 has compressive elasticity in an extending direction. The packing plate 16 is tightly fitted to an inner surface 21a of an opening peripheral wall 21 in the storage portion S. Since the fitting friction force of this tight fitting is set to be greater than the turning force based on the torsion coil spring 34, the lid body 11 is kept in the state illustrated in FIG. 2.

Meanwhile, as illustrated in FIG. 2, the leftward sliding of the lid 13 causes a left edge portion 13a of the lid 13 to partially protrude leftward from the case 1a and cancels the engagement between the lid 13 and the case 1a in the engagement portion Ka. Accordingly, when the user pushes (FIG. 2: arrow DR4) the left edge portion 13a rearward with the finger with force greater than the fitting friction force between the packing plate 16 and the storage portion S, the packing plate 16 is released from the storage portion S. Then, the lid body 11 turns (FIG. 3: arrow DR5) by itself about the axis CL11 due to the turning biasing force of the torsion coil spring 34 to be set to the open state illustrated in FIG. 3, and the inside of the storage portion S is opened.

Multiple card slots 41, 42, multiple connection terminals 43, 44 used to exchange data and signals with an external device, a microphone input terminal 45, and the like are provided inside the storage portion S. Since the turning angle of the lid body 11 is set to 90° or more, it is possible to easily insert and remove cards into and from the card slots 41, 42 and insert and remove plugs into and from the connection terminals 43, 44 and the microphone input terminal 45.

In order to close the open lid body 11, the user closes the lid body 11 by first turning it with the finger in the direction opposite to the arrow DR5 (clockwise as viewed from above) and sets the lid body 11 to the state illustrated in FIG. 2. In this case, since the last stage of the turning stroke is a stage in which the packing plate 16 is tightly fitted to the storage portion S, the resistance force increases.

The dimensions, the shapes, and the like of the lid body 11 are set such that the engagement between the grooves and the pocket portions in the engagement portion Ka will not progress, that is rightward sliding of the lid body 11 which is the next operation cannot be performed unless the angle of the lid body 11 relative to the case 1a reaches or falls below a predetermined angle in the turning of the lid body 11. In other words, when the lid body 11 is closed, causing the packing plate 16 to reach a position where the packing plate 16 can sufficiently seal the storage portion S by being tightly fitted thereto enables the rightward sliding of the lid body 11 to be performed next.

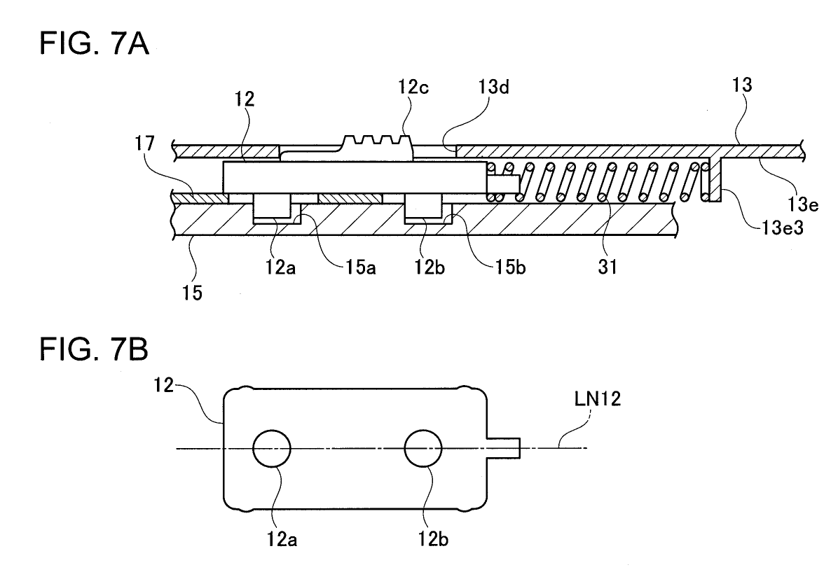

When the rightward sliding of the lid body 11 is to be performed, a force against the biasing force of the knob coil spring biasing the lock release knob 12 is necessary in addition to a force against the compression resilient forces of the slide coil springs 32, 33. As illustrated in FIG. 7A which is a cross-sectional view at the position S07-S07 in FIG. 1, the lock release knob 12 includes paired bosses 12a, 12b which are sliders configured to slide in paired cam grooves 15a, 15b formed in the holder 15. In detail, when the lid 13 is at the final position in the rightward sliding, the paired bosses 12a, 12b enter lock portions (passages CR2 to be described later) extending in the up-down direction in the cam grooves 15a, 15b to lock the sliding of the lid 13. The lock release knob 12 is made of a material with excellent sliding properties. An example of the material is a polyacetal resin.

The aforementioned opening-closing operation of the lid body 11 is achieved by the lid opening-closing structure K to be described next in detail.

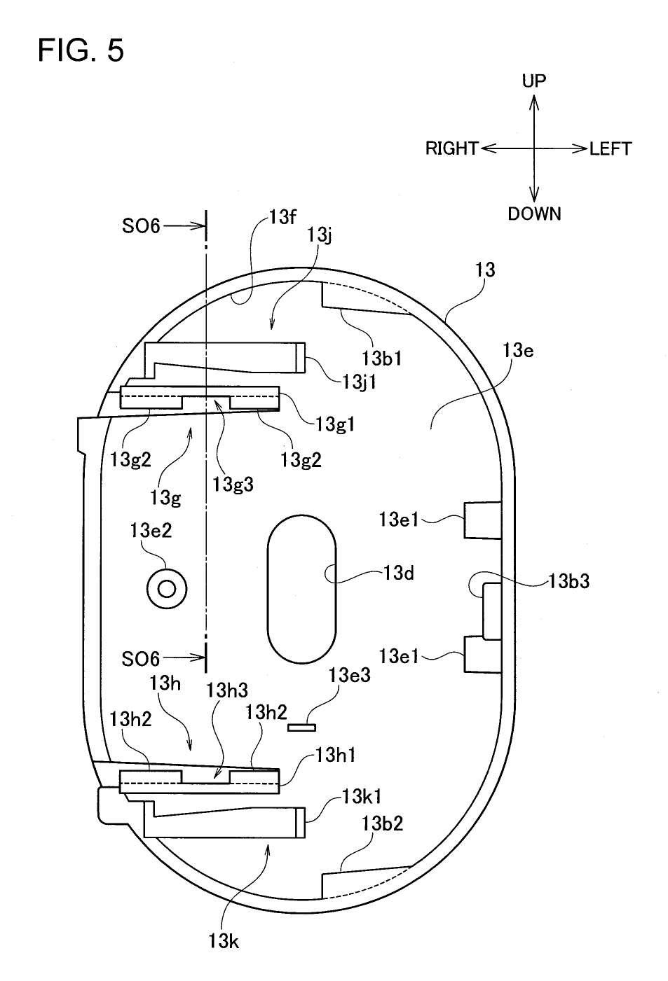

FIG. 5 illustrates a front plan of the lid 13 in the closed state. The directions of up, down, left, and right in FIG. 5 correspond to the directions in the closed state. The exterior shape of the lid 13 is a stadium elongating in the up-down direction and an example of the material of the lid 13 is a glass fiber reinforced polycarbonate (PC) resin. An opening portion 13d which elongates in the up-down direction is formed in a center portion of the lid 13. A protruding operation portion 12c (see FIGS. 4 and 7A) of the lock release knob 12 is inserted into this opening portion 13d to engage therewith and be movable in the up-down direction. A peripheral wall portion 13f stands at a peripheral edge of an inner surface 13e of the lid 13 (see also FIG. 3). The aforementioned upper rib 13b1 protrudes to extend leftward, rightward, and downward in an end portion of the peripheral wall portion 13f in an upper portion of the lid 13. The aforementioned lower rib 13b2 protrudes to extend leftward, rightward, and upward in an end portion of the peripheral wall portion 13f in a lower portion of the lid 13.

On the inner surface 13e of the lid 13, there are provided engagement portions 13e1, 13e1 to which paired protrusions 17a, 17a of a hold-down plate 17 (FIG. 4) are locked and a screw receiving boss 13e2 to which a screw N1 (FIG. 4) is screwed, the hold-down plate 17 (FIG. 4) holding down the lock release knob 12 by holding the lock release knob 12 between itself and the lid 13, the screw N1 used to fix the hold-down plate 17 whose one end is locked. Moreover, a spring receiving rib 13e3 which receives a lower end of the knob coil spring 31 (FIG. 4) is formed below the opening portion 13d on the inner surface 13e to protrude therefrom. Furthermore, paired holder engagement portions 13g, 13h extending in the left-right direction are provided on the inner surface 13e to be spaced away from each other in the up-down direction. Moreover, spring housing portions 13j, 13k are provided adjacent to the holder engagement portions 13g, 13h at positions near and outside the holder engagement portions 13g, 13h, respectively.

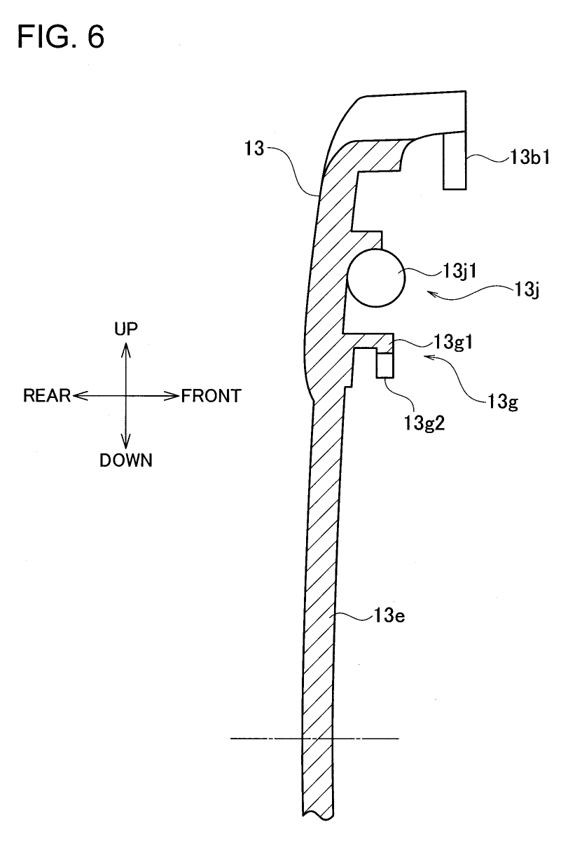

The cross-sectional shape of the holder engagement portion 13g is illustrated in FIG. 6 which is a cross-sectional view at the position S06-S06 in FIG. 5. The cross-sectional shape of the holder engagement portion 13h is a shape horizontally symmetric to the cross-sectional shape of the holder engagement portion 13g. As illustrated in FIGS. 5 and 6, the holder engagement portion 13g has an engagement wall portion 13g1 with a substantially L-shaped cross section. More specifically, the engagement wall portion 13g1 includes paired flange portions 13g2 protruding inward from distal end portion of the engagement wall portion 13g1 and spaced away from each other in the left-right direction. A portion between the paired flange portions 13g2 is a notch portion 13g3. The holder engagement portion 13h also has a similar shape and an engagement wall portion 13h1 includes paired flange portions 13h2 protruding inward from distal end portion of the engagement wall portion 13h1 and spaced away from each other in the left-right direction. A portion between the flange portions 13h2 is a notch portion 13h3.

The spring housing portions 13j, 13k house the slide coil springs 32, 33, respectively, and include restriction walls 13j1, 13k1 standing to restrict the positions of left ends of the slide coil springs 32, 33.

As illustrated in FIG. 4, the lock release knob 12 is supported by the hold-down plate 17 to be movable in the up-down direction by being held between the hold-down plate 17 and the inner surface 13e of the lid 13 with the operation portion 12c inserted to and engaging with the opening portion 13d. The lock release knob 12 is biased upward by the compression resilient force of the knob coil spring 31 inserted between the lock release knob 12 and the spring receiving rib 13e3 to such a position that the operation portion 12c comes into contact with an upper end of the opening portion 13d in a natural state.

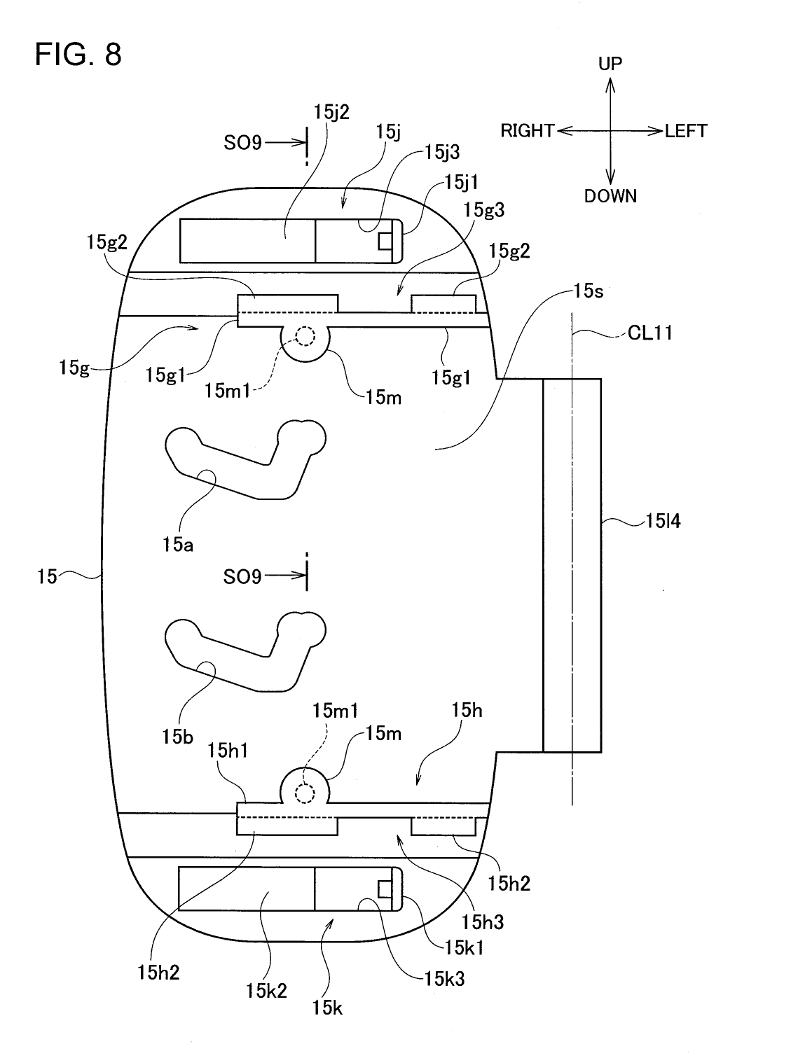

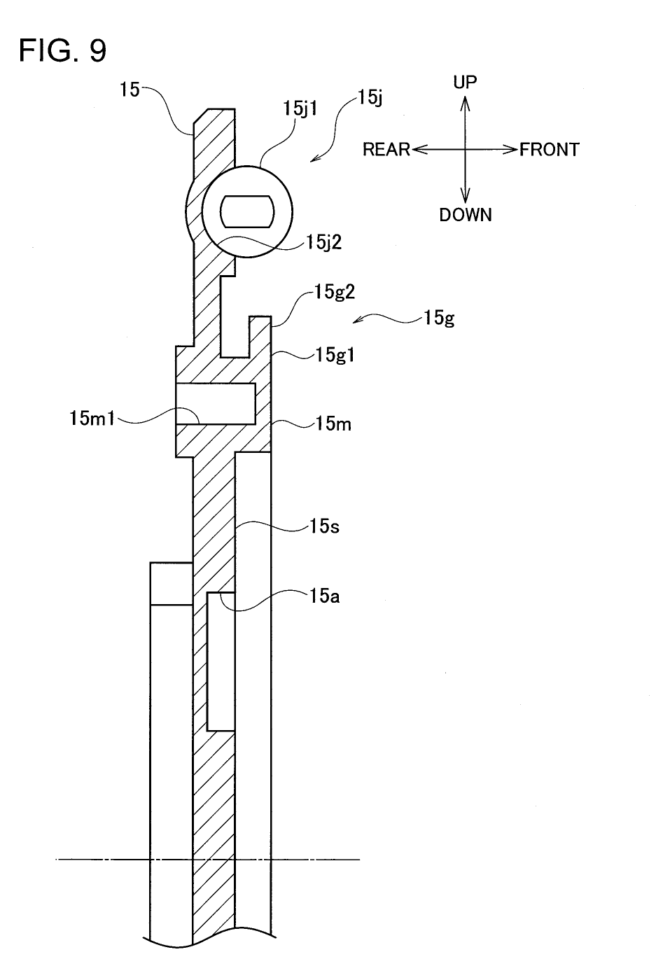

Next, the holder 15 is described with reference to FIGS. 4, 8, and 9. FIG. 8 is a rear plan of only the holder 15 in the closed state of the lid body 11. FIG. 9 is a cross-sectional view at the position S09-S09 in FIG. 8.

The holder 15 has a stadium shape which is slightly smaller than the lid 13 and which elongates in the up-down direction and an example of the material of the holder 15 is a glass fiber reinforced polycarbonate (PC) resin. A shaft 18 (FIG. 4) is inserted in the up-down direction in a right edge portion of the holder 15 and a holder hinge portion 1514 configuring the hinge portion 14 turnable about the axis CL11 relative to the case 1a is formed (the shape of the holder hinge portion 1514 is simplified in FIG. 8). The torsion coil spring 34 is fitted onto the shaft 18 and, as described above, the holder 15 is biased counterclockwise (in the opening direction) relative to the case 1a as viewed from above by the torsion resilient force of the torsion coil spring 34.

On a rear surface 15s facing the lid 13, the holder 15 includes lid engagement portions 15g, 15h which are spaced away from each other in the up-down direction and which engage with the holder engagement portions 13g, 13h of the lid 13. The lid engagement portions 15g, 15h include engagement wall portions 15g1, 15h1 and paired flange portions 15g2, 15h2 formed to be spaced way from each other in the left-right direction and to protrude outward from distal ends of the engagement wall portions 15g1, 15h1 to the upper side and the lower side, and are formed to have a substantially square U-shaped cross sections opening toward the outer side. Portions between the paired flange portions 15g2, 15h2 are formed to be notch portions 15g3, 15h3.

The holder 15 includes spring housing portions 15j, 15k which correspond to the spring housing portions 13j, 13k of the lid 13 and house the slide coil springs 32, 33, respectively. The spring housing portions 15j, 15k house the slide coil springs 32, 33 and include restriction walls 15j1, 15k1 which stand to restrict the positions of right ends of the slide coil springs 32, 33, respectively. In the spring housing portions 15j, 15k, portions opposite to the restriction walls 15j1, 15k1 are holding portions 15j2, 15k2 recessed in a U-shape and portions close to the restriction walls 15j1, 15k1 are opening portions 15j3, 15k3 which are holes penetrating the holder 15 in the front-rear direction.

The holder 15 includes paired screw receiving portions 15m, 15m protruding toward the viewer side of the sheet surface of FIG. 8 and having lower holes 15m1 to which paired screws N2 (FIG. 4) are screwed from the opposite side to the viewer of the sheet surface.

The packing plate 16 is a plate-shaped member having a shape corresponding to the external shape and size of the holder 15. The packing plate 16 is formed of a base plate member 16b which is slightly smaller than the external shape of the packing plate 16 and which is made of metal such as stainless steel and a cover portion 16c which covers substantially the entire surface of the base plate member 16b and which is made of silicone rubber or the like. Accordingly, the peripheral edge portion 16a of the packing plate 16 is formed only of silicone rubber and has at least compressive elasticity in the extending direction. The packing plate 16 includes through holes 16d at positions corresponding to the respective paired screw receiving portions 15m in the holder 15.

The paired cam grooves 15a, 15b are formed on the rear surface 15s of the holder 15 as recess portions.

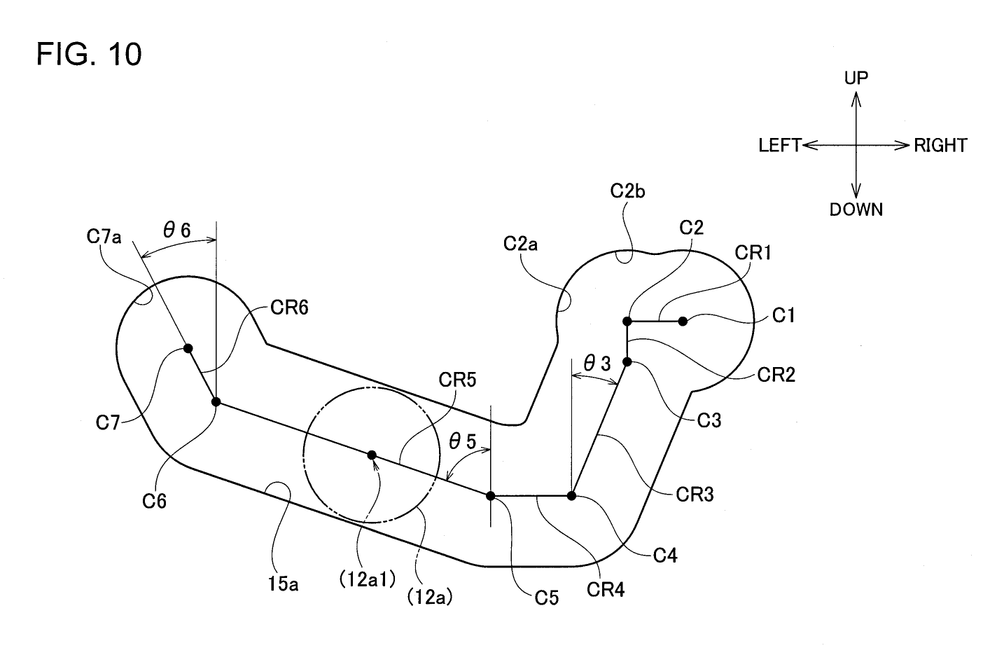

Since the cam grooves 15a, 15b have the same shape, the cam groove 15a is described next in detail as a representative. The description is given with reference to mainly FIG. 10 and includes operations from assembly of the lid body 11 to the lid opening operation.

The difference between the groove width of the cam groove 15a and the outer diameter of the boss 12a of the lock release knob 12 which slides in the cam groove 15a is very small and slide feeling (cam slide feeling) without looseness can be provided to the user.

The cam groove 15a includes a passage CR in which multiple straight passages are connected in series. In the following description, positions C1 to C7 at the center of the groove width are substantially the same as a center position 12a1 of the sliding boss 12a.

The passage CR includes a passage CR1 between the positions C1 and C2, a passage CR2 between the positions C2 and C3, a passage CR3 between the positions C3 and C4, a passage CR4 between the positions C4 and C5, a passage CR5 between the positions C5 and C6, and a passage CR6 between the positions C6 and C7.

The position C1 is a position of the boss 12a in the case where the holder 15 is attached to the lid 13 to which the lock release knob 12 is attached. Specifically, the holder 15 is attached to the lid 13 to which the lock release knob 12 attached by aligning and engaging the flange portions 15g2, 15h2 of the holder 15 with the notch portions 13g3, 13h3 of the lid 13 in a state where the slide coil springs 32, 33 are not installed. The center position 12a1 of the boss 12a is at the position C1 in this alignment.

Next, the slide coil springs 32, 33 are installed from the opening portions 15j3, 15k3 of the holder 15 into the spring housing portions 13j, 13k while being compressed. By this installing, the holder 15 is biased leftward by the compression resilient force of the slide coil springs 32, 33 and the boss 12a moves along the passage CR1 such that the center position 12a1 thereof is located at the position C2. Then, the boss 12a comes into contact with a left wall C2a and is restricted from moving leftward and alignment between the lid 13 and the holder 15 in the closed state is thereby achieved. Accordingly, even when someone tries to forcedly open the lid 13 leftward, the contact with the left wall C2a surely prohibits leftward sliding.

When the closed lid body 11 is to be opened, the lock release knob 12 is pushed downward against the upward biasing force of the knob coil spring 31. In this case, first, the center position 12a1 of the boss 12a moves, though slightly, directly downward along the passage CR2 from the position C2 to the position C3. In the passage CR2, since the boss 12a is in contact with the left wall C2a, the leftward sliding of the lid 13 is prohibited, although the leftward biasing force of the slide coil springs 32, 33 is applied to the lid 13.

Since the passage CR3 beyond the position C3 is tilted toward the lower left side, the lid 13 moves leftward while the lock release knob 12 is pushed downward. Specifically, the passage CR2 can provide a short time lag between the start of the push down operation of the lock release knob 12 by the user and the start of the leftward sliding and thereby provide a user with appropriate operation feeling which is not too sensitive.

When the center position 12a1 of the boss 12a reaches the position C4 (when the lid 13 slides by an amount corresponding to a horizontal length of the passage CR3), since the next passage CR4 is horizontal, the lid 13 is made to slide leftward along the passage CR4 at once by the leftward biasing force of the slide coil springs 32, 33.

Since the next passage CR5 is also a passage extending slightly upward, the lid 13 continuously and smoothly slides. In the passage CR5, the compression amount of the knob coil spring 31 is increased by the pushing down of the lock release knob 12 after the position C2 and the lock release knob 12 receives stronger upward compression resilient force. Accordingly, in the tilted passage CR5, a component force of the compression resilient force in a direction along the passage acts on the lid 13. Thus, the lid 13 is made to slide leftward by a resultant force of: component forces, in the direction along the passage CR5, of the horizontal compression resilient forces of the slide coil springs 32, 33; and the component force, in the direction along the passage CR5, of the compression resilient force of the knob coil spring 31. Hence, the sliding of the lid 13 in the passage CR5 is smoothly and quickly performed.

The center position 12a1 of the lock release knob 12 then reaches the position C6. The last passage CR6 to the position C7 beyond the position C6 is a tilted passage more upright than the passage CR5. In this stage, the compression amounts of the slide coil springs 32, 33 are small and the elastic resilient force thereof are small while the compression amount of the knob coil spring 31 is still large. Moreover, since the passage CR6 is an upward tilted passage extending further upward, the lid 13 receives a large component force, in a direction along the passage CR6, of the compression resilient force of the knob coil spring 31. Accordingly, in the last stage of the sliding, the center position 12a1 reaches the position C7 through passage CR6 at high speed and the boss 12a violently comes into contact with an inner wall C7a having an arc shape about the position C7 in the cam groove 15a. This contact generates a snapping sound being a collision sound. The user grasps the completion of the sliding from this collision sound and feels a sense of high-quality for the lid opening-closing structure K.

When the center position 12a1 of the boss 12a is at the position C7, the lid 13 is at an end position (leftmost position illustrated in FIG. 2) in a stroke of the leftward-rightward sliding relative to the holder 15. Moreover, when the center position 12a1 of the boss 12a is within a range close to the position C7 in the passage CR6 including the position C7, the engagement in the engagement portion Ka is canceled and the lid body 11 is openable. However, as described above, the packing plate 16 is tightly fitted to the inner surface 21a of the opening peripheral wall 21 in the storage portion S and fitting maintaining torque based on the fitting friction force between both members is set to be greater than the turning torque in the opening direction generated by the torsion coil spring 34 provided in the hinge portion 14. Accordingly, the lid body 11 is maintained in the state illustrated in FIG. 2 in which the lid 13 partially protrudes leftward from the case 1a. Moreover, the lock release knob 12 is automatically lifted (FIG. 2: broken line arrow DR3) in the movement of the boss 12a from the passage CR4 to the passage CR6.

Accordingly, when the user pushes the protruding portion of the lid 13 rearward with the finger and releases the packing plate 16 from the inner surface 21a of the storage portion S, the lid body 11 is turned approximately 90° to the open position by the turning torque of the torsion coil spring 34.

When the lid body 11 is to be closed from the open state, the lid body 11 is closed and the packing plate 16 is tightly fitted to the storage portion S. The inside of the storage portion is thereby waterproofed. Since the sliding and engagement of the lid 13 in the engagement portion Ka is possible at a sufficiently pressed-in turning position, the user sufficiently presses in the lid 13 and then pushes the lid 13 rightward. This causes the center position 12a1 of the boss 12a to first move through the passage CR6 from the position C7 to the position C6 illustrated in FIG. 10.

The passage CR6 is a passage extending downward with a tilt angle θ6 thereof relative to the up-down direction being less than 45° (for example, 23°). The passage CR5 subsequent to the passage CR6 is a passage more horizontal than the passage CR6 with a tilt angle θ5 thereof being 45° or more (for example, 71°). Accordingly, the resistance force felt at the finger of the user during the rightward pushing of the lid 13 is large in an initial stage and then immediately decreases. The user feels this change in the resistance force as click feeling in an operation. The user thereby grasps the start of the sliding and feels the sense of high quality for the lid opening-closing structure K.

When the user further pushes and moves the lid body 11 rightward against the resultant force of the leftward biasing component forces based on the slide coil springs 32, 33 and the knob coil spring 31, the boss 12a moves rightward in FIG. 10 through the passage CR5 and the center position 12a1 moves from the position C5 through the passage CR4 to reach the position C4. Since the tilt angle θ3 of the passage CR3 beyond the position C4 relative to the up-down direction is less than 45° (for example,) 22°, the upward compression resilient force of the knob coil spring 31 greatly acts on the boss 12a and the boss 12a automatically moves through the passage CR3 and the passage CR2 and the center position 12a1 reaches the position C2 which is a lock position and is maintained at the position C2.

Moreover, when the center position 12a1 reaches the position C2, the boss 12a violently comes into contact with an inner wall C2b having an arc shape about the position C2 in the cam groove 15a. Thus, a snapping sound being a collision sound is generated. The user grasps the completion of the locking of the lid body 11 from this collision sound and feels a sense of high-quality for the lid opening-closing structure K.

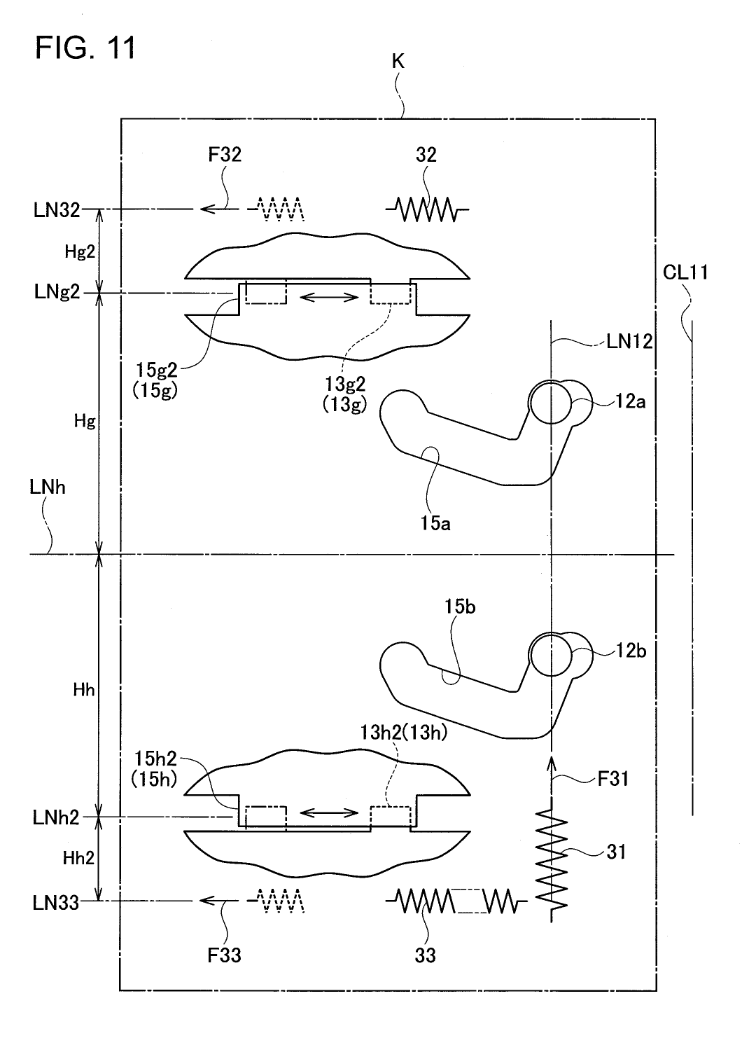

FIG. 11 schematically illustrates an engagement relationship between the lid 13 and the holder 15, a sliding relationship between the bosses 12a, 12b of the lock release knob 12 and the cam grooves 15a, 15b, and a relationship between points where the compression resilient forces of the knob coil spring 31 and the slide coil springs 32, 33 are applied in the lid opening-closing structure K described above in detail.

As illustrated in FIG. 11, in the lid opening-closing structure K, the cam grooves 15a, 15b are disposed respectively at positions above and below a center horizontal line LNh located at the center of the lid opening-closing structure K in the up-down direction to be equidistant from the center horizontal line LNh.

The bosses 12a, 12b engaging with and sliding in the respective cam grooves 15a, 15b are located on the same line LN12 extending in the up-down direction (see FIG. 7B), and the knob coil spring 31 biases the lock release knob 12, that is the bosses 12a, 12b upward with a compression resilient force F31 with the line LN12 being the axis of the knob coil spring 31. Specifically, the point where the compression resilient force F31 is applied to the lock release knob 12 and the points where the bosses 12a, 12b of the lock release knob 12 act on the cam grooves 15a, 15b are substantially on the same line LN12. Accordingly, the compression resilient force F31 of the knob coil spring 31 generates no rotation moment for the lid body 11. Thus, the sliding of the lid body 11 in the opening-closing operation is smoothly performed without the lid body 11 tilting.

As illustrated in FIG. 11, in the lid opening-closing structure K, a first engagement portion (holder engagement portion 13g and lid engagement portion 15g) is provided in one (upper portion) of upper and lower portions of the lid body 11 which are divided in a direction of the axis CL11 (up-down direction) and a second engagement portion (holder engagement portion 13h and lid engagement portion 15h) is provided in the other portion (lower portion). The border dividing the lid body 11 into the upper and lower portions is, for example, the center horizontal line LNh at the center in the up-down direction as described above. The engagement portions between the holder engagement portions 13g, 13h and the lid engagement portions 15g, 15h are disposed at positions in the upper and lower portions which are substantially symmetric with respect to the center horizontal line LNh. Specifically, the distance Hg from the center horizontal line LNh to an engagement line LNg2 is equal to the distance Hh from the center horizontal line LNh to an engagement line LNh2.

Moreover, action lines LN32 and LN33 of the slide coil springs 32, 33 which bias the lid 13 and the holder 15 in the left-right direction are located outside and near the engagement lines LNg2, LNh2, respectively, and the distance Hg2 between the action line LN32 and the engagement line LNg2 and the distance Hh2 between the action line LN33 and the engagement line LNh2 are equal to each other and are set to be small by arranging the lines close to one another. The compression resilient forces F32, F33 of the slide coil springs 32, 33 thereby generate almost no rotation moments for the lid 13 and the holder 15. Even if the rotation moments are generated, the rotation moments cancel each other out due to opposite action directions and are suppressed to an almost ignorable level. Accordingly, the opening-closing operation of the lid body 11 can be smoothly performed irrespective of the size and shape of the lid body 11 without the lid body 11 tilting.

As described above, in the lid opening-closing structure K, the compression resilient force F31 of the knob coil spring 31 and the compression resilient forces F32, F33 of the slide coil springs 32, 33 which are involved in the sliding in the opening-closing operation of the lid body 11 act as forces assisting the sliding while applying substantially no rotation moment to the sliding of the lid 13 relative to the holder 15, and also improve the user's feeling of the opening-closing operation.

Moreover, the lid opening-closing structure K includes the upper engagement portion Ka1 and the lower engagement portion Kat in both end portions of the lid 13 in the longitudinal direction thereof and the side engagement portion Ka3 in the side edge portion of the lid 13 as the engagement portion Ka which prohibits the open turning of the lid body 11 in the closed state thereof. Specifically, the engagement portion Ka restricts the open turning of the lid body 11 in the two end portions in the direction of the turning axis CL11 of the lid body 11 and in the edge portion farthest from the axis CL11. The closed state in which the storage portion S is waterproofed can be thereby more surely maintained even when the lid body 11 is large or has a shape elongating in one direction.

The example described above in detail is not limited to the aforementioned configuration and may be modified as a modified example within a scope not departing from the spirit of the present invention.

The electronic device provided with the lid opening-closing structure K is not limited to the aforementioned video camera 51. The lid opening-closing structure K can be applied to various devices including a radio device such as a handy transceiver, an information processing device such a mobile terminal, and the like. Moreover, the lid opening-closing structure K may be applied to an electronic device to provide a dust-proof function. The aforementioned directions of up, down, left, right, front, and rear are set for the sake of explaining the case where the electronic device is the video camera 51, and do not limit the attitude and the usage mode of the lid opening-closing structure K. Accordingly, the turning direction of the lid body 11 is not limited to the horizontal direction and may be any direction.

The knob coil spring 31 which biases the lock release knob 12 and the slide coil springs 32, 33 which bias the lid 13 in the sliding direction are not limited compression coil springs and may be replaced by biasing members of other modes. For example, the springs 31, 32, 33 may be tension coil springs or leaf springs. The cams on which the bosses 12a, 12b slide is not limited to the aforementioned cam grooves 15a, 15b which are grooves. For example, the cams may be steps or rib-shaped cams. The direction in which the lid 13 slides relative to the holder 15 does not have to be the direction orthogonal to the axis CL11 of the hinge portion 14, and may be a direction intersecting the axis CL11.

What is claimed is:

1. A waterproof lid opening-closing structure comprising:
a packing member tightly fitted to the opening portion and configured to close an opening portion of a case;
a holder connected to the case by a hinge portion and to which the packing member is attached, the holder configured to turn about an axis of the hinge portion between a closed position where the packing member closes the opening portion and an open position where the packing member opens the opening portion;
a lid engaging with the holder in an engagement portion configured to allow the lid to slide by a predetermined stroke in a direction intersecting the axis;
a slide biasing member biasing the lid in a direction away from the axis;
a lock release knob attached to the lid and which is movable to a first position where the sliding of the lid relative to the holder is restricted and a second position where the sliding is allowed; and
a lock biasing member biasing the lock release knob toward the first position, wherein
the engagement portion includes a first engagement portion formed in one of two portions of the lid which are divided in a direction of the axis and a second engagement portion formed in another one of the two portions, and
the slide biasing member includes a first slide biasing member disposed outside and adjacent to the first engagement portion and a second slide biasing member disposed outside and adjacent to the second engagement portion.

2. The waterproof lid opening-closing structure according to claim 1, wherein when a line dividing the lid into the two portions passes a center of a length of the lid in the direction of the axis, the first engagement portion and the second engagement portion are equidistant from the line dividing the lid.

3. The waterproof lid opening-closing structure, according to claim 1, further comprising:
a slider formed in the lock release knob to protrude toward the holder; and
a cam portion provided in the holder and in which the slider slides while engaging with the cam portion with the sliding of the lid, wherein
the lock biasing member biases the lock release knob on an imaginary line passing the slider in a plan of the cam portion,
the cam portion includes a tilted passage which causes a component force biasing the lid in a direction away from the axis to be generated for the slider based on a biasing force of the lock biasing member in the sliding of the lid.

4. The waterproof lid opening-closing structure according to claim 1, further comprising a case engagement portion formed in the lid and the case, the case engagement portion configured to be engageable with the case to restrict the turning of the lid about the hinge portion when the lid is not near an end of the predetermined stroke on the opposite side to the axis and configured to disengage from the case to allow the turning of the lid about the hinge portion when the lid is near the end.

5. The waterproof lid opening-closing structure according to claim 4, wherein the case engagement portion is provided in each of at least three portions including: paired edge portions on both sides of the lid in the direction of the axis; and an edge portion of the lid away from the axis.

6. An electronic device comprising:
the waterproof lid opening-closing structure according claim 1; and
a card slot or a connector to which a card or a plug is insertable from outside through the opening portion when the packing member is at the open position.
